(19) United States
(12) Patent Application Publication
(10) Pub. No.: US 2006/0226003 A1
(43) Pub. Date: Oct. 12, 2006

(54) Apparatus and methods for ionized deposition of a film or thin layer

(76) Inventors: John Mize, Spokane, WA (US); Kenneth Niemela, Deer Park, WA (US); Steven Wu, Veradale, WA (US)

Correspondence Address: BINGHAM, MCCUTCHEN LLP, THREE EMBARCADERO CENTER, 18 FLOOR, SAN FRANCISCO, CA, 94111-4067, US

(21) Appl. No.: 10/542,040

(22) PCT Filed: Jan. 21, 2004
(86) PCT No.: PCT/US04/01798

§ 371 Date: Feb. 6, 2006

Related U.S. Application Data
(60) Provisional application No. 60/441,999, filed on Jan. 22, 2003.

(51) Int. Cl. C23C 14/00

(52) U.S. Cl. 204/298.01

(57) ABSTRACT

A coil assembly (200) is described herein that comprises a) at least one coil (220) with a width (240); and b) at least one boss (210) coupled to the at least one coil, wherein the at least one boss comprises at least two support sections. Methods of forming and/or producing coil assemblies are described herein and comprise a) providing a coil; b) providing at least one boss having at least two support sections; and c) coupling the at least one boss to the coil.

### FIELD OF THE INVENTION

The field of the invention is thin layer or film production by using ionized deposition.

### BACKGROUND OF THE INVENTION

Electronic and semiconductor components are used in ever-increasing numbers of consumer and commercial electronic products, communications products and data-exchange products. Examples of some of these consumer and commercial products are televisions, computers, cell phones, pagers, palm-type or handheld organizers, portable radios, car stereos, or remote controls. As the demand for these consumer and commercial electronics increases, there is also a demand for those same products to become smaller and more portable for the consumers and businesses.

As a result of the size decrease in these products, the components that comprise the products must also become smaller and/or thinner. Examples of some of those components that need to be reduced in size or scaled down are microelectronic chip interconnections, semiconductor chip components, resistors, capacitors, printed circuit or wiring boards, wiring, keyboards, touch pads, and chip packaging.

When electronic and semiconductor components are reduced in size or scaled down, any defects that are present in the larger components are going to be exaggerated in the scaled down components. Thus, the defects that are present or could be present in the larger component should be identified and corrected, if possible, before the component is scaled down for the smaller electronic products.

In order to identify and correct defects in electronic, semiconductor and communications components, the components, the materials used and the manufacturing processes for making those components should be broken down and analyzed. Electronic, semiconductor and communication/data-exchange components are composed, in some cases, of layers of materials, such as metals, metal alloys, ceramics, inorganic materials, polymers, or organometallic materials. The layers of materials are often thin (on the order of less than a few tens of angstroms in thickness). In order to improve on the quality of the layers of materials, the process of forming the layer—such as physical vapor deposition of a metal or other compound—should be evaluated and, if possible, modified and improved.

In order to improve the process of depositing a layer of material, the surface and/or material composition must be measured, quantified and defects or imperfections detected. In the case of the deposition of a layer or layers of material, its not the actual layer or layers of material that should be monitored but the material and surface of that material that is being used to produce the layer of material on a substrate or other surface and the intervening apparatus, such as a coil or collimator, that are placed between the target material and the substrate or other surface that should be monitored. For example, when depositing a layer of metal onto a surface or substrate by sputtering a target comprising that metal, the atoms and molecules being deflected or liberated from the target must travel a path to the substrate or other surface that will allow for an even and uniform deposition. Atoms and molecules traveling natural and expected paths after deflection and/or liberation from the target will uneven deposition on the surface or substrate, including trenches and holes in the surface or substrate. For certain surfaces and substrates, it may be necessary to redirect the atoms and molecules leaving the target in order to achieve a more uniform deposition, coating and/or film on the surface or substrate.

To this end, it would be desirable to develop and utilize a deposition apparatus and sputtering chamber system that will maximize uniformity of the coating, film or deposition on a surface and/or substrate. Coils and coil sets, such as those that are being produced by Honeywell Electronic Materials™, are consumable products placed inside the sputtering chamber or ionized plasma apparatus that redirect sputtered atoms and/or molecules to form a more uniform film and/or layer on a substrate and/or suitable surface. For background purposes, the coil is present in these systems and/or deposition apparatus as an inductively coupling device to create a secondary plasma of sufficient density to ionize at least some of the metal atoms that are sputtered from the target. In an ionized metal plasma system, the primary plasma forms and is generally confined near the target by the magnetron, and subsequently gives rise to atoms, such as Ti atoms, being ejected from the target surface. The secondary plasma formed by the coil system produces Ti, Cu & Ta ions (depending on material being sputtered). These metal ions are then attracted to the wafer by the field in the sheath that forms at the substrate (wafer) surface. As used herein, the term “sheath” means a boundary layer that forms between a plasma and any solid surface. This field can be controlled by applying a bias voltage to the wafer and/or substrate.

Conventional coils and coils sets can be expensive and difficult to manufacture because of the size of the metal or metal alloy rod being used. For example, in some coil sets a tantalum rod that is about 1″ to about 1.3″ in diameter to produce the bosses (supports and connections) of the coils. Therefore, it would be desirable to develop thinner, smaller and ultimately more cost efficient coils and coil sets for utilization with a deposition apparatus, a sputtering chamber system and/or ionized plasma deposition system. It would also be desirable to ensure that those new coils and coil sets will have a similar lifetime relative to the target being used, because decreasing the difference in lifetime between the coils, coil sets and targets would, at the very least, decrease the number of times the apparatus or systems have to be shut down to replace coils before replacing both the coil and target.

### SUMMARY OF THE INVENTION

A coil assembly is described herein that comprises a) at least one coil; and b) at least one boss coupled to the at least one coil, wherein the at least one boss comprises at least two support sections. Methods of forming and/or producing coil assemblies are described herein and comprise a) providing a coil; b) providing at least one boss having at least two support sections; and c) coupling the at least one boss to the coil.

### BRIEF DESCRIPTION OF THE FIGURES

FIG. 1 shows a schematic diagram of a contemplated boss design.

FIG. 2 shows a schematic diagram of a contemplated coil assembly.

FIG. 3 shows a schematic diagram of a contemplated coil assembly.

FIG. 4 shows a schematic diagram of a contemplated coil assembly.

FIG. 5 shows a schematic diagram of a contemplated sputtering assembly.

### DESCRIPTION OF THE SUBJECT MATTER

Thinner, smaller and ultimately more cost efficient coils and coil sets for utilization with a deposition apparatus, a sputtering chamber system and/or ionized plasma deposition system have surprisingly been developed and will be disclosed herein. These new coils and coil sets have a similar lifetime relative to the target being used, because as stated earlier, decreasing the difference in lifetime between the coils, coil sets and targets would, at the very least, decrease the number of times the apparatus or systems have to be shut down to replace coils before replacing both the coil and target.

In order to accomplish the goals of increasing the cost efficiency of the coils and coil sets while decreasing the amount of material used, minimizing the difference in lifetime between the coil and/or coil set and the target, and maximizing the uniformity of the film, coating and/or layer deposited on the substrate, a coil set has been developed that utilizes smaller diameter bosses and in some embodiments utilizes smaller, thinner coils.

Specifically, a coil assembly is described herein that comprises a) at least one coil; and b) at least one boss coupled to the at least one coil, wherein the at least one boss comprises at least two support sections. Methods of forming and/or producing coil assemblies are described herein and comprise a) providing a coil; b) providing at least one boss having at least two support sections; and c) coupling the at least one boss to the coil.

A contemplated coil assembly comprises at least one coil and in some contemplated embodiments, a coil assembly comprises at least two coils. As described below, contemplated coils may comprise any suitable material including metals or metal alloys. Contemplated coils may have any suitable thickness, depending on the needs of the application. It should be understood; however, that the bosses described herein allow for coil thicknesses that are significantly less than conventional coil thicknesses. In some embodiments, contemplated coils are those coils that are considered “thin”. As used herein, the phrase “thin coils” means coils that comprise a thickness of less than about 0.2 inches. In other contemplated embodiments, coils comprise a thickness of less than about 0.13 inches. In yet other embodiments, coils comprise a thickness of less than about 0.1 inches to about 0.010 inches. The coil may also have a height and/or a diameter. In some embodiments, the height of the coil is less than about 3 inches. In other embodiments, the height of the coil is less than about 2.5 inches. In yet other embodiments, the height of the coil is less than about 2 inches. And in other embodiments, the height of the coil is less than about 1.5 inches.

In addition, a contemplated coil assembly comprises at least one boss coupled to the at least one coil, wherein the at least one boss comprises at least two support sections. Contemplated boss(es) are coupled to the coil through a screw, a bolt or bolt assembly, a welded joint, wherein the welded joint is formed utilizing conventional welding techniques or other more non-conventional techniques, such as laser welding or e-beam welding. The boss(es) may also be formed in a mold when the coil is formed by using conventional molding techniques such as injection molding.

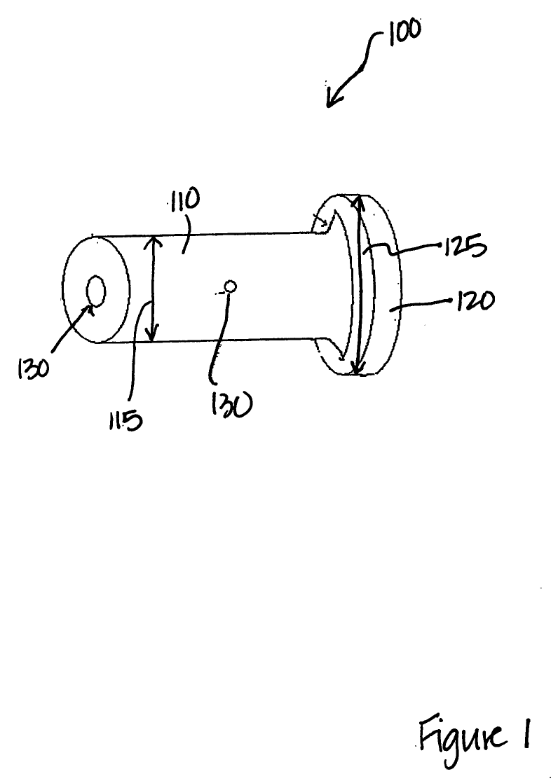

FIGS. 1-4 show schematic diagrams of one boss design contemplated herein and how at least one boss might be coupled to the coil material. It should be understood, however, that the at least one boss may comprise any suitable shape as long as the goals previously mentioned are substantially met. As used herein, the term “boss” means a support device that couples to at least one of the coil material, the sputtering chamber material and/or the electrical connection material. As used herein, the term “coupled” means a physical attachment of two parts of matter or components (adhesive, attachment interfacing material) or a physical and/or chemical attraction between two parts of matter or components, including bond forces such as covalent and ionic bonding, and non-bond forces such as Van der Waals, electrostatic, coulombic, hydrogen bonding and/or magnetic attraction. In contemplated embodiments, the boss material comprises the same material as the coil and/or the target material; however, it is not always necessary that the boss material, the coil material and the target material be the same. For example, the coil may comprise tantalum and the at least one boss may comprise a tantalum alloy, such as TaN.

The material used to produce the boss may comprise any suitable material, such as those listed below as suitable for the target material, however, it is contemplated that the material will comprise a material that is at least similar and/or compatible to the coil material and/or the target material. In addition, the at least one boss may comprise a diameter that is significantly smaller than conventional boss diameters, including those diameters less than or equal to about 0.7″. In preferred embodiments, the diameter of the at least one boss is less than or equal to about 0.5″, and in additional preferred embodiments, the diameter of the at least one boss is less than or equal to about 0.4″.

In some embodiments, the at least one boss comprises a size, shape and at least two distinct diameters. In yet other embodiments, the at least one boss may comprise two or more different shapes, sizes and/or diameters, depending on the needs of the customer and/or vendor, the requirements of the deposition apparatus and/or the materials available during construction of the coil and/or coil set. The at least two distinct diameters of the at least one boss are formed by coupling together support sections, wherein each support section has a diameter. For example, one contemplated boss 100 shown in FIG. 1 comprises a first section 110 that has a diameter 115, wherein this section is not coupled directly to the coil (not shown) and a second section 120 that is coupled to the first section 110, that is coupled to the coil and that has a diameter 125 that is larger than the diameter 115 of the first section 110. Boss 100 also comprises openings 130 that are also characterized as “vent holes” that aid in ventilation of the screw holes after a support screw (not shown) is applied. In this embodiment, the first section is coupled to the coil through the second section. It is contemplated that if there are more than one boss coupled to the core that each boss may have a different size, shape and/or diameter than the other boss or bosses coupled to the coil.

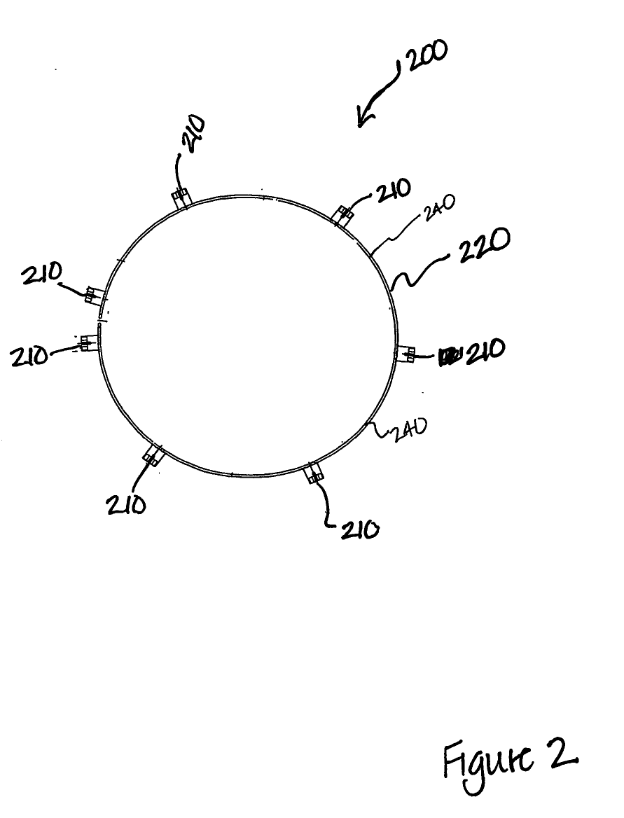

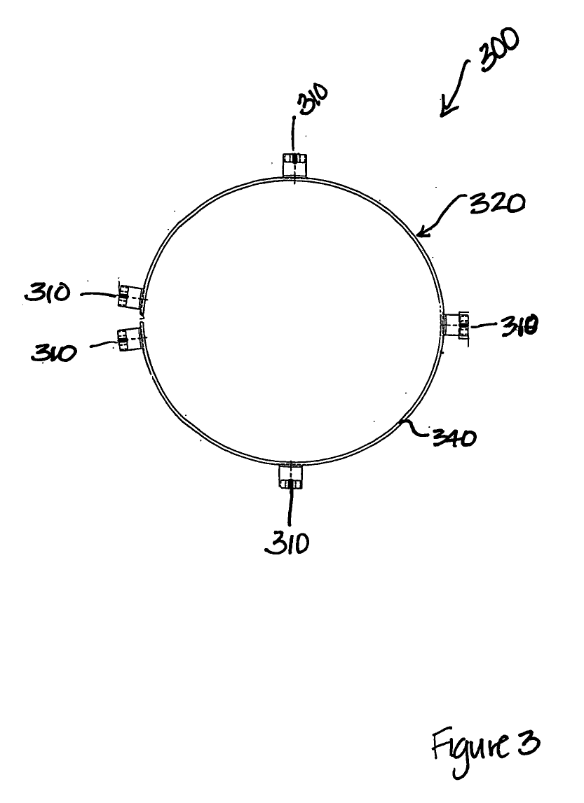

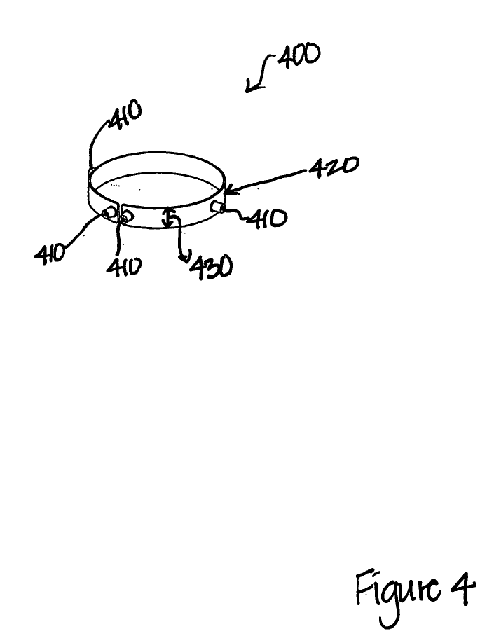

The at least one boss may comprise as few as one boss coupled to the coil material and as many as ten boss coupled to the coil material. In yet other embodiments, some and/or all of the boss may be also coupled to the walls of the deposition apparatus and/or coupled to the electrical connections. FIGS. 2-4 show contemplated coil assemblies 200-400 wherein a plurality of bosses 210, 310 and 410 are coupled to a coil 220, 320 and 420. FIG. 4 also shows that coils such as coil 420 have a height 430. FIGS. 2 and 3 are overhead views of the coil assemblies showing only the width 240 and 340 of the coil 220 and 320.

As mentioned earlier, the boss is designed in part to provide support for the coil material, so it is not necessary that each and every boss be coupled to the walls of the deposition apparatus. In some embodiments, the boss may couple coil material to coil material. In some embodiments, the boss and/or bosses not only provide support for the coil, but also act as heat transfer devices to transfer heat from the coil and/or the deposition chamber/apparatus to the outer part of the apparatus. In some embodiments, the heat transfer device is and/or acts like a heat pipe to channel heat out of the chamber or sputtering area. The transfer of heat from the coil and/or the chamber leads to a more stable secondary plasma without significant convection.

In a similar manner as the at least one boss, the coil may comprise any suitable material that is at least similar to and/or compatible to the boss material and/or the target material. In additional embodiments, the coil may be produced such that it is thinner or smaller than conventional coils and/or coil sets.

The current applied to the coil or coil set in the deposition apparatus can be tailored and/or designed to be suitable to the smaller diameter boss design and, in some embodiments, the smaller diameter material used to produce the coil in order to produce a similar atom and/or molecular path achieved in the conventional coil and/or coil set. It should be understood that the current and the size of the bosses and/or coil should work together to be suitable to direct the atoms and/or molecules being sputtered from the target to the surface and/or substrate in a manner such that the deposition of the atoms and/or molecules are more uniform than conventional apparatus and methods currently produce.

In some embodiments, it would also be ideal to include a sensing system that would a) comprise a simple device/apparatus and/or mechanical setup and a simple method for determining wear, wear-out and/or deterioration of a surface or material; b) would notify the operator when maintenance is necessary, as opposed to investigating the quality of the material on a specific maintenance schedule; and c) would reduce and/or eliminate material waste by reducing and/or eliminating premature replacement or repair of the material. Sensing devices and sensor systems contemplated herein can be found in U.S. Provisional Application Serial No.: 60/410540, which is incorporated herein in its entirety.

Methods of forming and/or producing coil assemblies are described herein and comprise a) providing a coil; b) providing at least one boss having at least two support members; and c) coupling the at least one boss to the coil. The coil and/or the at least one boss may be provided by any suitable method, including a) buying at least some of the coil and/or the at least one boss from a supplier; b) preparing or producing at least some of the coil and/or the at least one boss in house using materials provided by another source and/or c) preparing or producing the coil and/or the at least one boss in house using materials also produced or provided in house or at the location. The coupling of the at least one boss and the coil may be accomplished by utilizing one or several of the coupling methods and apparatus previously discussed herein.

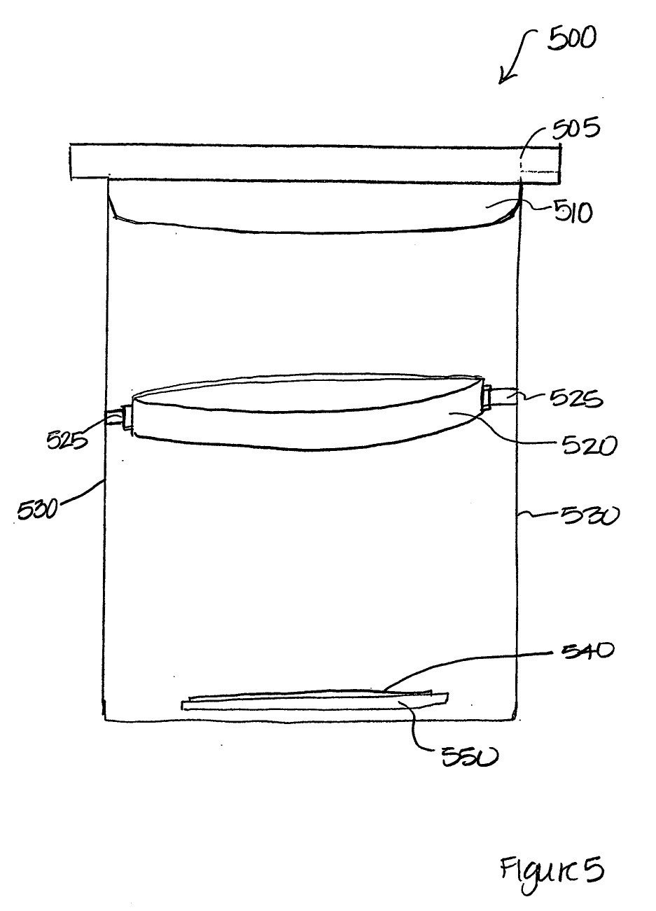

FIG. 5 shows a contemplated sputtering target assembly 500 comprising a sputtering target 510 and a coil 520 with a plurality of bosses 525, wherein the sputtering target 510 is coupled to a back plate 505 and wherein the coil 520 is coupled to at least one sidewall 530 through at least one boss 525. A layer 540 is formed on substrate 550 by atoms sputtering from the target 510.

Sputtering targets and sputtering target assemblies, such as that shown in FIG. 5, contemplated herein comprise any suitable shape and size depending on the application and instrumentation used in the PVD process. Sputtering targets contemplated herein also comprise a surface material and a core material (which includes the backing plate), wherein the surface material is coupled to the core material through and/or around a gas chamber or gas stream. The surface material and core material may generally comprise the same elemental makeup or chemical composition/component, or the elemental makeup and chemical composition of the surface material may be altered or modified to be different than that of the core material. In most embodiments, the surface material and the core material comprise the same elemental makeup and chemical composition. However, in embodiments where it may be important to detect when the target's useful life has ended or where it is important to deposit a mixed layer of materials, the surface material and the core material may be tailored to comprise a different elemental makeup or chemical composition.

The surface material is that portion of the target that is exposed to the energy source at any measurable point in time and is also that part of the overall target material that is intended to produce atoms and/or molecules that are desirable as a surface coating.

Sputtering targets, coils and/or bosses may generally comprise any material that can be a) reliably formed into a sputtering target, coils and/or bosses; b) sputtered from the target (and sometimes the coil) when bombarded by an energy source; and c) suitable for forming a final or precursor layer on a wafer or surface. It should be understood that although the coil comprises materials that are considered the same or similar to those materials being sputtered, the coil may or may not sputter atoms. Coil sputtering depends primarily on the coil bias with respect to the plasma and the wafer. Materials that are contemplated to make suitable sputtering targets, coils and/or bosses are metals, metal alloys, conductive polymers, conductive composite materials, conductive monomers, dielectric materials, hardmask materials and any other suitable sputtering material. As used herein, the term “metal” means those elements that are in the d-block and f-block of the Periodic Chart of the Elements, along with those elements that have metal-like properties, such as silicon and germanium. As used herein, the phrase “d-block” means those elements that have electrons filling the 3d, 4d, 5d, and 6d orbitals surrounding the nucleus of the element. As used herein, the phrase “f-block” means those elements that have electrons filling the 4f and 5f orbitals surrounding the nucleus of the element, including the lanthanides and the actinides. Preferred metals include titanium, silicon, cobalt, copper, nickel, iron, zinc, vanadium, zirconium, aluminum and aluminum-based materials, tantalum, niobium, tin, chromium, platinum, palladium, gold, silver, tungsten, molybdenum, cerium, promethium, thorium or a combination thereof. More preferred metals include copper, aluminum, tungsten, titanium, cobalt, tantalum, magnesium, lithium, silicon, manganese, iron or a combination thereof. Most preferred metals include copper, aluminum and aluminum-based materials, tungsten, titanium, zirconium, cobalt, tantalum, niobium or a combination thereof. Examples of contemplated and preferred materials, include aluminum and copper for superfine grained aluminum and copper sputtering targets; aluminum, copper, cobalt, tantalum, zirconium, and titanium for use in 200 mm and 300 mm sputtering targets, along with other mm-sized targets; and aluminum for use in aluminum sputtering targets that deposit a thin, high conformal “seed” layer of aluminum onto surface layers. It should be understood that the phrase “and combinations thereof” is herein used to mean that there maybe metal impurities in some of the sputtering targets, such as a copper sputtering target with chromium and aluminum impurities, or there may be an intentional combination of metals and other materials that make up the sputtering target, such as those targets comprising alloys, borides, carbides, fluorides, nitrides, silicides, oxides and others.

The term “metal” also includes alloys, metal/metal composites, metal ceramic composites, metal polymer composites, as well as other metal composites. Alloys contemplated herein comprise gold, antimony, arsenic, boron, copper, germanium, nickel, indium, palladium, phosphorus, silicon, cobalt, vanadium, iron, hafnium, titanium, iridium, zirconium, tungsten, silver, platinum, tantalum, tin, zinc, lithium, manganese, rhenium, and/or rhodium. Specific alloys include gold antimony, gold arsenic, gold boron, gold copper, gold germanium, gold nickel, gold nickel indium, gold palladium, gold phosphorus, gold silicon, gold silver platinum, gold tantalum, gold tin, gold zinc, palladium lithium, palladium manganese, palladium nickel, platinum palladium, palladium rhenium, platinum rhodium, silver arsenic, silver copper, silver gallium, silver gold, silver palladium, silver titanium, titanium zirconium, aluminum copper, aluminum silicon, aluminum silicon copper, aluminum titanium, chromium copper, chromium manganese palladium, chromium manganese platinum, chromium molybdenum, chromium ruthenium, cobalt platinum, cobalt zirconium niobium, cobalt zirconium rhodium, cobalt zirconium tantalum, copper nickel, iron aluminum, iron rhodium, iron tantalum, chromium silicon oxide, chromium vanadium, cobalt chromium, cobalt chromium nickel, cobalt chromium platinum, cobalt chromium tantalum, cobalt chromium tantalum platinum, cobalt iron, cobalt iron boron, cobalt iron chromium, cobalt iron zirconium, cobalt nickel, cobalt nickel chromium, cobalt nickel iron, cobalt nickel hafnium, cobalt niobium hafaium, cobalt niobium iron, cobalt niobium titanium, iron tantalum chromium, manganese iridium, manganese palladium platinum, manganese platinum, manganese rhodium, manganese ruthenium, nickel chromium, nickel chromium silicon, nickel cobalt iron, nickel iron, nickel iron chromium, nickel iron rhodium, nickel iron zirconium, nickel manganese, nickel vanadium, tungsten titanium and/or combinations thereof.

As far as other materials that are contemplated herein for sputtering targets, coils and/or bosses, the following combinations are considered examples of contemplated sputtering targets, coils and/or bosses (although the list is not exhaustive): chromium boride, lanthanum boride, molybdenum boride, niobium boride, tantalum boride, titanium boride, tungsten boride, vanadium boride, zirconium boride, boron carbide, chromium carbide, molybdenum carbide, niobium carbide, silicon carbide, tantalum carbide, titanium carbide, tungsten carbide, vanadium carbide, zirconium carbide, aluminum fluoride, barium fluoride, calcium fluoride, cerium fluoride, cryolite, lithium fluoride, magnesium fluoride, potassium fluoride, rare earth fluorides, sodium fluoride, aluminum nitride, boron nitride, niobium nitride, silicon nitride, tantalum nitride, titanium nitride, vanadium nitride, zirconium nitride, chromium silicide, molybdenum silicide, niobium silicide, tantalum silicide, titanium silicide, tungsten silicide, vanadium silicide, zirconium silicide, aluminum oxide, antimony oxide, barium oxide, barium titanate, bismuth oxide, bismuth titanate, barium strontium titanate, chromium oxide, copper oxide, hafnium oxide, magnesium oxide, molybdenum oxide, niobium pentoxide, rare earth oxides, silicon dioxide, silicon monoxide, strontium oxide, strontium titanate, tantalum pentoxide, tin oxide, indium oxide, indium tin oxide, lanthanum aluminate, lanthanum oxide, lead titanate, lead zirconate, lead zirconate-titanate, titanium aluminide, lithium niobate, titanium oxide, tungsten oxide, yttrium oxide, zinc oxide, zirconium oxide, bismuth telluride, cadmium selenide, cadmium telluride, lead selenide, lead sulfide, lead telluride, molybdenum selenide, molybdenum sulfide, zinc selenide, zinc sulfide, zinc telluride and/or combinations thereof.

Thin layers or films produced by the sputtering of atoms or molecules from targets discussed herein can be formed on any number or consistency of layers, including other metal layers, substrate layers, dielectric layers, hardmask or etchstop layers, photolithographic layers, anti-reflective layers, etc. In some preferred embodiments, the dielectric layer may comprise dielectric materials contemplated, produced or disclosed by Honeywell International, Inc. including, but not limited to: a) FLARE (polyarylene ether), such as those compounds disclosed in issued patents U.S. Pat. No. 5,959,157, U.S. Pat. No. 5,986,045, U.S. Pat. No. 6,124,421, U.S. Pat. No. 6,156,812, U.S. Pat. No. 6,172,128, U.S. Pat. No. 6,171,687, U.S. Pat. No. 6,214,746, and pending application Ser. Nos. 09/197478, 09/538276, 09/544504, 09/741634, 09/651396, 09/545058, 09/587851, 09/618945, 09/619237, 09/792606, b) adamantane-based materials, such as those shown in pending application Ser. No. 09/545058; Serial PCT/US01/22204 filed Oct. 17, 2001; PCT/US01/50182 filed Dec. 31, 2001; application Ser. No. 60/345374 filed Dec. 31, 2001; application Ser. No. 60/347195 filed Jan. 8, 2002; and application Ser. No. 60/350187 filed Jan. 15, 2002; c) commonly assigned U.S. Pat. Nos. 5,115,082; 5,986,045; and 6,143,855; and commonly assigned International Patent Publications WO 01/29052 published Apr. 26, 2001; and WO 01/29141 published Apr. 26, 2001; and (d) nanoporous silica materials and silica-based compounds, such as those compounds disclosed in issued patents U.S. Pat. No. 6,022,812, U.S. Pat. No. 6,037,275, U.S. Pat. No. 6,042,994, U.S. Pat. No. 6,048,804, U.S. Pat. No. 6,090,448, U.S. Pat. No. 6,126,733, U.S. Pat. No. 6,140,254, U.S. Pat. No. 6,204,202, U.S. Pat. No. 6,208,014, and pending application Ser. Nos. 09/046474, 09/046473, 09/111084, 09/360131, 09/378705, 09/234609, 09/379866, 09/141287, 09/379484, 09/392413, 09/549659, 09/488075, 09/566287, and 09/214219 all of which are incorporated by reference herein in their entirety and (e) Honeywell HOSP® organosiloxane.

The wafer or substrate may comprise any desirable substantially solid material. Particularly desirable substrates would comprise glass, ceramic, plastic, metal or coated metal, or composite material. In preferred embodiments, the substrate comprises a silicon or germanium arsenide die or wafer surface, a packaging surface such as found in a copper, silver, nickel or gold plated leadframe, a copper surface such as found in a circuit board or package interconnect trace, a via-wall or stiffener interface (“copper” includes considerations of bare copper and its oxides), a polymer-based packaging or board interface such as found in a polyimide-based flex package, lead or other metal alloy solder ball surface, glass and polymers such as polyimides. In more preferred embodiments, the substrate comprises a material common in the packaging and circuit board industries such as silicon, copper, glass, or a polymer.

Substrate layers contemplated herein may also comprise at least two layers of materials. One layer of material comprising the substrate layer may include the substrate materials previously described. Other layers of material comprising the substrate layer may include layers of polymers, monomers, organic compounds, inorganic compounds, organometallic compounds, continuous layers and nanoporous layers.

As used herein, the term “monomer” refers to any chemical compound that is capable of forming a covalent bond with itself or a chemically different compound in a repetitive manner. The repetitive bond formation between monomers may lead to a linear, branched, super-branched, or three-dimensional product. Furthermore, monomers may themselves comprise repetitive building blocks, and when polymerized the polymers formed from such monomers are then termed “blockpolymers”. Monomers may belong to various chemical classes of molecules including organic, organometallic or inorganic molecules. The molecular weight of monomers may vary greatly between about 40 Dalton and 20000 Dalton. However, especially when monomers comprise repetitive building blocks, monomers may have even higher molecular weights. Monomers may also include additional groups, such as groups used for crosslinking.

As used herein, the term “crosslinking” refers to a process in which at least two molecules, or two portions of a long molecule, are joined together by a chemical interaction. Such interactions may occur in many different ways including formation of a covalent bond, formation of hydrogen bonds, hydrophobic, hydrophilic, ionic or electrostatic interaction. Furthermore, molecular interaction may also be characterized by an at least temporary physical connection between a molecule and itself or between two or more molecules.

Contemplated polymers may also comprise a wide range of functional or structural moieties, including aromatic systems, and halogenated groups. Furthermore, appropriate polymers may have many configurations, including a homopolymer, and a heteropolymer. Moreover, alternative polymers may have various forms, such as linear, branched, super-branched, or three-dimensional. The molecular weight of contemplated polymers spans a wide range, typically between 400 Dalton and 400000 Dalton or more.

Examples of contemplated inorganic compounds are silicates, aluminates and compounds containing transition metals. Examples of organic compounds include polyarylene ether, polyimides and polyesters. Examples of contemplated organometallic compounds include poly(dimethylsiloxane), poly(vinylsiloxane) and poly(trifluoropropylsiloxane).

The substrate layer may also comprise a plurality of voids if it is desirable for the material to be nanoporous instead of continuous. Voids are typically spherical, but may alternatively or additionally have any suitable shape, including tubular, lamellar, discoidal, or other shapes. It is also contemplated that voids may have any appropriate diameter. It is further contemplated that at least some of the voids may connect with adjacent voids to create a structure with a significant amount of connected or “open” porosity. The voids preferably have a mean diameter of less than 1 micrometer, and more preferably have a mean diameter of less than 100 nanometers, and still more preferably have a mean diameter of less than 10 nanometers. It is further contemplated that the voids may be uniformly or randomly dispersed within the substrate layer. In a preferred embodiment, the voids are uniformly dispersed within the substrate layer.

### EXAMPLES

As shown in FIGS. 1-4, a contemplated boss maybe a two diameter pin comprising two support structures with an unchanged tapped #8 screw hole, wherein the larger diameter support structure is e-beam welded to the outer diameter of the coil and/or coil material. It should be understood that other mounting devices may be used in place of the screws. This coil design utilizes the smaller boss, thus reducing the cost of the coil set. Also, because the bosses are thinner and, in some cases longer, the same coil could be made thinner, ultimately decreasing the difference between the target and the coil life. The boss and/or coil, in this Example, could be made of a lesser grade of tantalum or other material.

In this Example, the at least one boss is made with a CNC-lathe that does turning, boring and 4^{th} axis milling. The CNC-lathe has live tooling and a single bar feeder. The at least one boss is made of 395 or 495 tantalum and e-beam welded to a 0.125″×2″ round coil. The coil is then used in a sputtering chamber for the ENCORE® system. The coil has 200 mm and 300 mm designs where the 200 mm designs where the 200 mm design comprises at least 5 bosses and the 300 mm comprises at least 7 bosses. The specific dimensions of the contemplated boss arrangement and size for this Example are, again, shown in FIGS. 1-4. It should be understood; however, that this example is not meant to limit the scope of the subject matter presented herein.

Thus, specific embodiments and applications of apparatus and methods for ionized deposition of a film or layer have been disclosed. It should be apparent, however, to those skilled in the art that many more modifications besides those already described are possible without departing from the inventive concepts herein. The inventive subject matter, therefore, is not to be restricted except in the spirit of the disclosure and claims herein. Moreover, in interpreting the disclosure and claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

We claim:

1. A coil assembly, comprising:
at least one coil;
at least one boss coupled to the at least one coil, wherein the at least one boss comprises at least two support sections.

2. The coil assembly of claim 1, wherein the coil comprises a metal or a metal alloy.

3. The coil assembly of claim 2, wherein the metal or metal alloy comprises a transition metal.

4. The coil assembly of claim 3, wherein the transition metal comprises tantalum or titanium.

5. The coil assembly of claim 1, wherein the at least one boss comprises more than 3 bosses.

6. The coil assembly of claim 5, wherein the at least one boss comprises more than 5 bosses.

7. The coil assembly of claim 1, wherein the at least one boss comprises the same material as the coil.

8. The coil assembly of claim 1, wherein the at least one boss is coupled to the coil through a welded joint.

9. The coil assembly of claim 8, wherein the welded joint is formed by laser welding or e-beam welding.

10. The coil assembly of claim 1, wherein the at least one boss is molded to the coil as one continuous piece of material.

11. The coil assembly of claim 1, wherein the at least one boss comprises a first support section and a second support section and wherein the diameter of the first support section is different from the diameter of the second support section.

12. An ion depositing apparatus comprising the coil assembly of claim 1.

13. A sputtering chamber assembly comprising the ion depositing apparatus of claim 12.

14. A sputtering chamber assembly comprising the coil assembly of claim 1.

15. The coil assembly of claim 1, wherein the assembly comprises a heat transfer device.

16. The coil assembly of claim 15, wherein the heat transfer device comprises the at least one boss.

17. The coil assembly of claim 15, wherein the heat transfer device comprises the at least one boss and the coil.

18. The coil assembly of claim 1, wherein the coil comprises a thickness of less than about 0.2 inches.

19. The coil assembly of claim 18, wherein the coil comprises a thickness of less than about 0.13 inches.

20. A method of producing a coil assembly, comprises:
providing a coil;
providing at least one boss having at least two support sections; and
coupling the at least one boss to the coil.

21. The method of claim 20, wherein the coil comprises a metal or a metal alloy.

22. The method of claim 21, wherein the metal or metal alloy comprises a transition metal.

23. The method of claim 22, wherein the transition metal comprises tantalum or titanium.

24. The method of claim 20, wherein the at least one boss comprises more than 3 bosses.

25. The method of claim 24, wherein the at least one boss comprises more than 5 bosses.

26. The method of claim 20, wherein the at least one boss comprises the same material as the coil.

27. The method of claim 20, wherein the at least one boss is coupled to the coil through a welded joint.

28. The method of claim 27, wherein the welded joint is formed by laser welding or e-beam welding.

29. The method of claim 20, wherein the at least one boss is molded to the coil as one continuous piece of material.

30. The method of claim 20, wherein the at least one boss comprises a first support section and a second support section and wherein the diameter of the first support section is different from the diameter of the second support section.

31. An ion depositing apparatus comprising the coil assembly produced by the method of claim 20.

32. A sputtering chamber assembly comprising the ion depositing apparatus of claim 31.

33. A sputtering chamber assembly comprising the coil assembly produced by the method of claim 20.

34. The method of claim 20, wherein the assembly comprises a heat transfer device.

35. The method of claim 34, wherein the heat transfer device comprises the at least one boss.

36. The method of claim 34, wherein the heat transfer device comprises the at least one boss and the coil.

37. The method of claim 20, wherein the coil comprises a thickness of less than about 0.2 inches.

38. The method of claim 37, wherein the coil comprises a thickness of less than about 0.13 inches.
